(19) United States
(12) Patent Application Publication
(10) Pub. No.: US 2014/0332369 A1
(43) Pub. Date: Nov. 13, 2014

(54) MULTIDIRECTIONAL RACETRACK ROTARY CATHODE FOR PVD ARRAY APPLICATIONS

(71) Applicants: Evelyn Scheer, Stockstadt (DE); Markus Hanika, Landsberg (DE); Ralph Lindenberg, Budingen-Rinderbugen (DE); Marcus Bender, Hanau (DE); Andreas Lopp, Freigericht-Somborn (DE); Konrad Schwanitz, Aschaffenburg (DE); Fabio Pieralisi, Aschaffenburg (DE); Jian Liu, Grosskrotzenburg (DE)

(72) Inventors: Evelyn Scheer, Stockstadt (DE); Markus Hanika, Landsberg (DE); Ralph Lindenberg, Budingen-Rinderbugen (DE); Marcus Bender, Hanau (DE); Andreas Lopp, Freigericht-Somborn (DE); Konrad Schwanitz, Aschaffenburg (DE); Fabio Pieralisi, Aschaffenburg (DE); Jian Liu, Grosskrotzenburg (DE)

(73) Assignee: APPLIED MATERIALS, INC., Santa Clara, CA (US)

(21) Appl. No.: 14/353,473

(22) PCT Filed: Oct. 11, 2011
(86) PCT No.: PCT/EP2011/068552

§ 371 Date: Jul. 25, 2014

(51) Int. Cl. H01J 37/32; C23C 14/35

(52) U.S. Cl. CPC H01J 37/32532; C23C 14/35
USPC 204/192.1; 204/298.12

(57) ABSTRACT

A cathode assembly for a sputter deposition apparatus and a method for coating a substrate is provided. The cathode assembly has a coating side for coating on a substrate. Further, the cathode assembly includes a rotary target assembly adapted for rotating a target material around a rotary axis; at least a first magnet having an inner magnet pole and at least one outer magnet poles and being adapted for generating one or more plasma regions. The cathode assembly has a first angular coordinate for a magnet pole, the magnet pole being provided for the coating side, and a second angular coordinate for a further magnet pole, the magnet pole being provided for the coating side; wherein the first angular coordinate and the second angular coordinate define an angle a larger than about 20 degrees and smaller than about 160 degrees.

### TECHNICAL FIELD OF THE INVENTION

Embodiments of the present invention relate to a cathode assembly for a deposition apparatus and a method of depositing a film on a substrate. Embodiments of the present invention particularly relate to a cathode assembly for a sputter deposition apparatus and a method for depositing a film on a substrate in a sputter deposition apparatus. Specifically, embodiments refer to a cathode assembly having a magnet assembly and a method for depositing a film using a magnetic field.

### BACKGROUND OF THE INVENTION

Coated materials may be used in several applications and in several technical fields. For instance, substrates for displays are often coated by a physical vapor deposition (PVD) process. Further applications of coated materials include insulating panels, organic light emitting diode (OLED) panels, as well as hard disks, CDs, DVDs and the like.

Several methods are known for coating a substrate. For instance, substrates may be coated by a PVD process, a chemical vapor deposition (CVD) process, or a plasma enhanced chemical vapor deposition (PECVD) process etc. Typically, the process is performed in a process apparatus or process chamber, where the substrate to be coated is located. A deposition material is provided in the apparatus. In the case that a PVD process is used, the deposition material is present in the solid phase in a target. By bombarding the target with energetic particles, atoms of the target material, i.e. the material to be deposited, are ejected from the target. The atoms of the target material are deposited on the substrate to be coated. Typically, a PVD process is suitable for thin film coatings.

In a PVD process, the target is used to serve as cathode. Both are arranged in a vacuum deposition chamber. A process gas is filled in the process chamber at a low pressure (for instance at about 10⁻² mbar). When voltage is applied to the target and the substrate, electrons are accelerated to the anode, whereby ions of the process gas are generated by the collision of the electron with the gas atoms. The positively charged ions are accelerated in the direction of the cathode. By impingement of the ion, atoms of target material are ejected from the target.

Cathodes are known which use a magnetic field in order to increase the efficiency of the above described process. By applying a magnetic field, electrons spend more time near the target, and more ions are generated near the target. In known cathode assemblies, one or more magnet yokes or magnet bars are arranged in order to ameliorate the ion generation and, thus, the deposition process. Some cathode arrangements provide movable magnet assemblies in a cathode in order to reach a uniform layer deposition with high efficiency.

However, since the movement (such as turning) of the magnet bar is time consuming and requires considerable hardware as well as software efforts to drive the magnet assembly, a movable magnet bar or yoke is cost intensive and error prone.

In view of the above, it is an object of the present invention to provide a cathode assembly and a method for depositing a film on a substrate, which overcomes at least some of the problems in the art.

### SUMMARY OF THE INVENTION

In light of the above, a cathode assembly for a sputter deposition apparatus according to independent claim 1 and a method depositing a film on a substrate in a sputter deposition apparatus according to independent claim 14 are provided. Further aspects, advantages, and features of the present invention are apparent from the dependent claims, the description, and the accompanying drawings.

According to a first embodiment of the present invention, a cathode assembly for a sputter deposition apparatus having a coating side for coating on a substrate is provided. The cathode assembly includes a rotary target assembly adapted for rotating a target material around a rotary axis and at least a first magnet assembly. The at least one magnet assembly has typically an inner magnet pole and at least one outer magnet pole and being adapted for generating one or more plasma regions. Further, the cathode assembly has a first angular coordinate for a magnet pole and a second angular coordinate for a further magnet pole. Typically, the magnet poles being provided for the coating side. The first angular coordinate and the second angular coordinate define an angle α larger than about 20 degrees and smaller than about 160 degrees.

According to a further embodiment of the present invention, a method for depositing a film on a substrate in a sputter deposition apparatus is provided. The sputter deposition apparatus may include a rotary target assembly and a coating side for coating on a substrate. Typically, the target assembly is adapted for rotating a target material around a rotary axis. Further, the cathode assembly may include at least one magnet assembly held in a fixed position with respect to the rotary axis. The magnet assembly includes an inner magnet pole and at least one outer magnet pole and is adapted for generating one or more plasma regions. Typically, the cathode assembly further has a first angular coordinate for a magnet pole, the magnet pole being provided for the coating side, and a second angular coordinate for a further magnet pole, the magnet pole being provided for the coating side. The method for depositing a film on a substrate includes generating at least one first plasma region with a magnetic field generated by a magnet pole being arranged in the first angular coordinate and at least one second plasma region with a magnetic field generated by a magnet pole being arranged in the second angular coordinate for coating the substrate at the coating side. Typically, the first angular coordinate and the second angular coordinate define an angle α larger than about 20 degrees and smaller than about 160 degrees.

According to a yet further embodiment, a cathode assembly for a sputter deposition apparatus is provided. Typically, the cathode assembly has a coating side for coating on a substrate. Further, the cathode assembly includes a rotary target assembly adapted for rotating a target material around a rotary axis and at least a first magnet assembly. The magnet assembly includes an inner magnet pole and at least one outer magnet pole and is adapted for generating one or more plasma regions. Typically, the inner magnet pole and an outer magnet pole of the at least one magnet pole define an angle α larger than about 20 degrees and smaller than about 160 degrees. According to yet further embodiments, features from the dependent claims or combinations of dependent claims can be optionally added.

According to a further embodiment, a cathode assembly) for a sputter deposition apparatus is provided. The cathode assembly has a coating side for coating on a substrate and a rotary target assembly adapted for rotating a target material around a rotary axis. Further, the cathode assembly includes at least a first magnet assembly having an inner magnet pole and at least one outer magnet pole and being adapted for generating one or more plasma regions and at least a second magnet assembly having an second inner magnet pole and at least one second outer magnet poles and being adapted for generating one or more plasma regions. Typically, the inner magnet pole and the second inner magnet pole define an angle α larger than about 20 degrees and smaller than about 160 degrees. According to yet further embodiments, features from the dependent claims or combinations of dependent claims can be optionally added.

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a deposition chamber suitable for a PVD process according to embodiments described herein;

FIG. 2 shows a schematic cross sectional view of a cathode assembly according to embodiments described herein;

FIG. 3 shows a schematic cross sectional view of a cathode assembly according to embodiments described herein;

FIG. 4 shows a schematic cross sectional view of a cathode including cathode assemblies according to embodiments described herein;

FIG. 5a shows a schematic cross sectional view of a magnet assembly according to embodiments described herein;

FIG. 5b shows a schematic top view of the magnet assembly shown in FIG. 5a according to embodiments described herein;

FIG. 6a shows a schematic cross sectional view of a magnet assembly according to embodiments described herein;

FIG. 6b shows a schematic top view of the magnet assembly shown in FIG. 5a according to embodiments described herein; and

FIG. 7 shows a flow diagram of a method for depositing a film according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

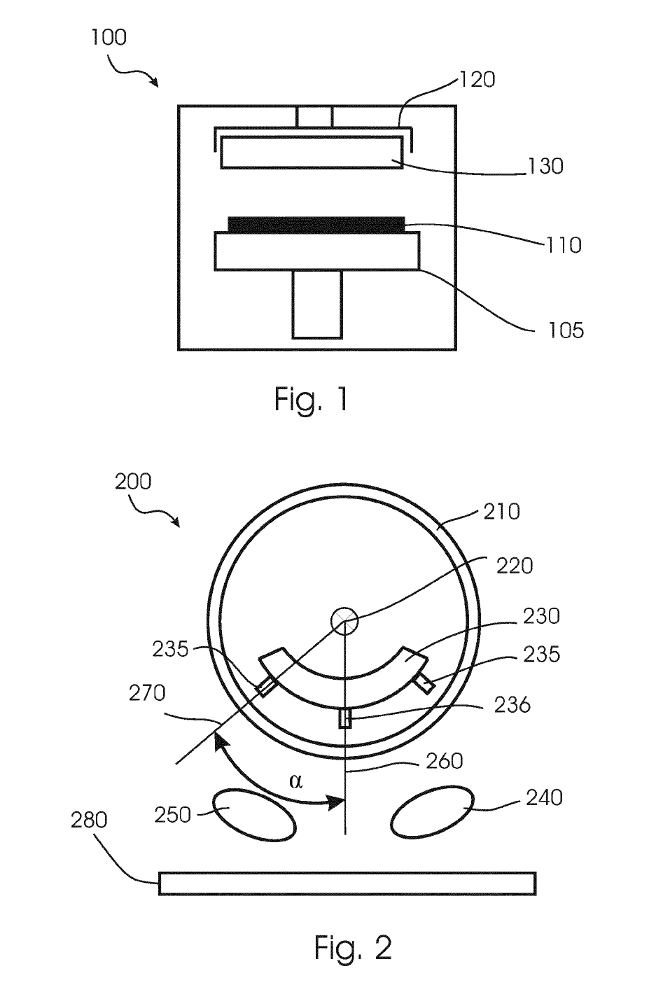

FIG. 1 shows a deposition chamber suitable for a PVD process according to embodiments described herein. Typically, chamber 100 includes a substrate support 105, which is adapted for carrying a substrate 110. Further, chamber 100 includes a device 120 for receiving and holding a cathode assembly 130. The cathode assembly 130 may include a target providing the material to be deposited on substrate 110. According to some embodiments, the cathode assembly 130 and the device 120 for receiving and holding are adapted to rotate the cathode assembly 130.

As used herein, the term “cathode assembly” should be understood as an assembly which is adapted and suitable for being used as a cathode in a deposition process, such as a sputter deposition process. For instance, the cathode assembly may include a body as a basis. Typically, the body of the cathode assembly may be adapted to be cooled, for instance, by a cooling fluid flowing through it. The cathode assembly may further include target material, which may be mounted to the body in solid form. Typically, the target material may contain the material to be deposited during the deposition process. The cathode assembly may be adapted to be mounted in a deposition chamber and may include respective connections. For instance, the cathode assembly may be rotatable around a rotary axis of the cathode assembly and may be adapted for being rotatably mounted in the deposition chamber. Further, a cathode assembly may include one or more magnet assemblies for generating a magnetic field.

The term “magnet assembly” as used herein should be understood as an assembly including one or more magnet poles for generating one or more magnetic fields. For instance, a magnet assembly may contain two magnet poles of adverse polarity, such as two magnet elements being arranged so as to generate two magnetic fields. Typically, the arrangement of magnet poles in the magnet assembly may enable a magnetic field to be generated in a substantially tunnel shape. A magnet assembly providing a magnetic field with the shape of a tunnel in a closed loop shape may be denoted as a race track. Typically, the magnet assembly may be adapted for being located in a cathode assembly as described above.

Typically, the cathode assembly according to embodiments described herein includes a magnet assembly. The magnet assembly may be arranged within the cathode assembly and may include two magnet poles, such as magnet bars, magnetic material or the like. Due to the higher amount of process gas ions (as described above) near the target, higher deposition rates are possible with cathode assemblies including one or more magnet assemblies. Further, magnet assemblies in the cathode of a PVD deposition process chamber, allow for using a lower voltage difference between cathode and anode than cathode assemblies without magnet assembly.

Cathode assemblies known in the art include a magnet assembly, which is rotatable around a rotary axis of the cathode assembly. The rotation of the magnet assembly around the rotary axis of the cathode assembly results in a more uniform deposition of material on the substrate compared to a non-rotating magnet assembly. The uniformity of the material deposition refers for instance to the layer thickness and layer resistance. The rotation around the rotary axis may be provided in a wobbling mode or in a split sputter mode. The movement of the magnet assembly inside the target is for instance used for large-area PVD systems in a static deposition.

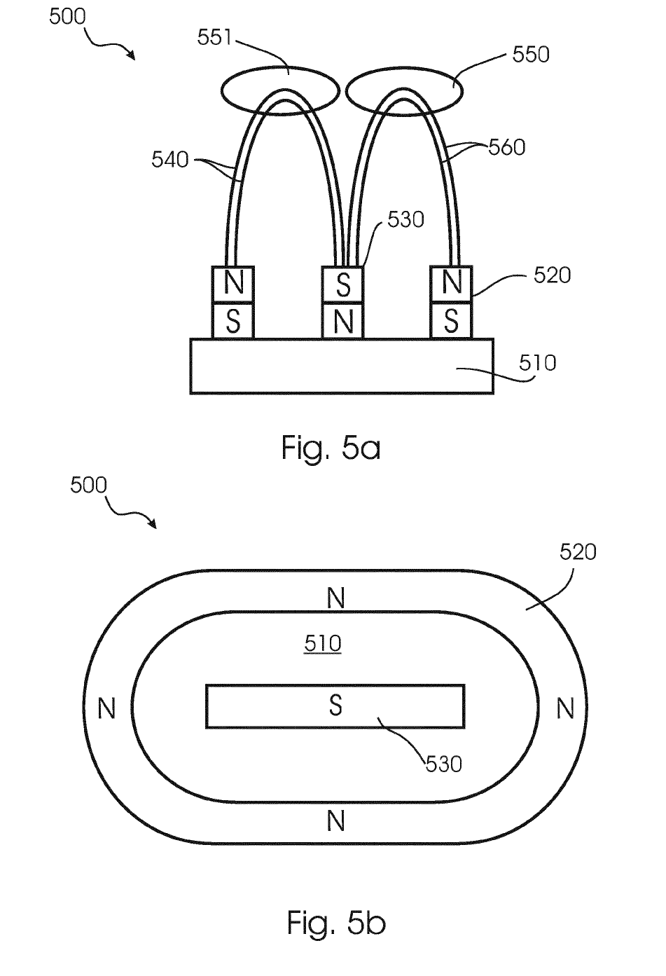

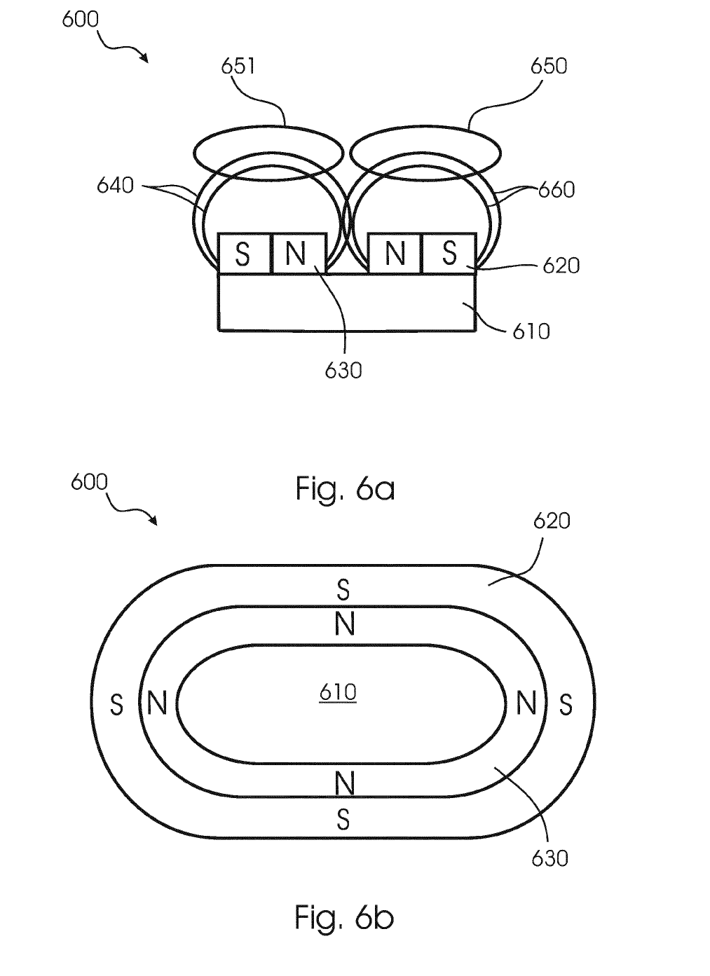

According to embodiments described herein, a cathode assembly, including one or more magnet assemblies held in a fixed position relative to the rotary axis of the cathode assembly, is provided. Typically, the magnet assemblies include magnet poles and/or magnets. Embodiments of magnet assemblies are described in detail with respect to FIGS. 5A, 5b, 6a, and 6b. Typically, at least one magnet assembly is provided within the cathode assembly. The magnet assembly typically includes at least three magnet poles, such as an inner magnet pole and at least one outer magnet pole. According to some embodiments, the magnet poles are arranged in a racetrack shape and are adapted to generate a magnetic field having a racetrack shape.

Typically, magnetic fields are generated by the one or more magnet assemblies. The magnetic fields cause plasma regions to be formed near the magnetic fields. According to typical embodiments described herein, the plasma regions caused by the magnetic fields are built up in a multi-directional way. Typically, the multi-directional way may be realized by different arrangements or designs of the one or more magnet assemblies and the magnet poles in the cathode assembly. For instance, the magnet assembly and/or magnet assemblies may be arranged in a multi-directional way at the coating side of the cathode assembly, typically at a single coating side of the cathode assembly. Generally, the cathode assembly is adapted so that a first angular coordinate for a magnet pole and a second angular coordinate for a further magnet pole are provided. The first and second angular coordinates of the cathode assembly are typically located at the coating side for coating one substrate.

According to some embodiments, the angle α between the first angular coordinate and the second angular coordinate is larger than about 20 degrees and smaller than about 160 degrees. The angle α between the first angular coordinate and the second angular coordinate is more typically between about 30 degrees and 120 degrees, and even more typically between about 50 and about 100 degrees. According to one embodiment, the angle between the first and the second angular coordinate is larger than about 30 degrees and smaller than about 80 degrees. In one example, the angle between the first and the second angular coordinate is about 60 degrees.

According to some embodiments, the inner pole of a first magnet assembly is arranged at the first angular coordinate of the cathode assembly and one of the outer poles of the first magnet assembly is arranged at the second angular coordinate. According to some further embodiments, the inner pole of a first magnet assembly is arranged at the first angular coordinate and the inner pole of a second magnet assembly is arranged at the second angular coordinate. Typically, the angle between the first angular coordinate and the second angular coordinate is the angle α as described above. Typically, the angles defined above can essentially correspond to the angles of the plasma regions generated by the magnet assembly/the magnet assemblies. This may be particularly true for symmetric magnet assemblies wherein the plasma regions are essentially formed symmetrically with respect to the magnet assembly components. For instance, the plasma regions may be formed corresponding to the placement of the magnet poles. Accordingly, according to some embodiments, which can be combined with other embodiments described herein, defining position and angles with respect to the plasma regions herein can correspondingly apply to the respective components of the one or more magnet assemblies, such as the magnet poles, magnet elements and the like.

Typically, the angle between the magnetic poles and/or the first and the second plasma regions may be provided using one or more magnet assemblies arranged in a fixed position in the cathode assembly. Having multidirectional racetracks in one rotary cathode according to embodiments described herein saves both time and equipment costs.

Generally, the angle between the first angular coordinate and the second angular coordinate is measured in substantially one plane. According to some embodiments, the plane containing the first angular coordinate and the second angular coordinate may be a cross-sectional plane of the cathode assembly at a defined longitudinal position. Typically, the plane in which the first and second angular coordinates are arranged may be substantially perpendicular to the longitudinal axis (such as the rotary axis) of the cathode assembly. As can be seen in the FIGS. 2 to 4, the angle α is measured in a cross-sectional plane of the cathode assembly. As an example, the cross-sectional plane may be a plane at about 50% of the extension along the longitudinal (or rotary) axis of the cathode assembly.

FIG. 2 shows a cross-sectional view of a cathode assembly according to some embodiments described herein. Typically, the cathode assemblies as described herein with respect to FIGS. 2 to 4 may be used in a PVD chamber as described with respect to FIG. 1. The cathode assembly 200 provides a rotary target assembly providing target material 210. The target material may be arranged in one piece, as shown in the embodiment of FIG. 2 or may be arranged in several target tiles. The cathode assembly 200 includes a rotary axis 220 around which the cathode assembly is rotatable.

In the embodiment shown in FIG. 2, one magnet assembly 230 is provided. Typically, the magnet assembly is provided within the cathode assembly. According to some embodiments, the magnet assembly 230 is adapted to be held in a fixed position with respect to the cathode assembly. In other words, the magnet assembly 230 may rotate with the cathode assembly 200 with respect to a substrate 280, but the magnet assembly is in a fixed position with respect to rotary axis 220 of the cathode assembly 200. Typically, the side of the cathode at which the magnet assembly is located may be referred to as the coating side. In FIG. 2 the coating side can be seen by a substrate 280 being arranged at the coating side of the cathode assembly 200.

According to some embodiments, the magnet assembly 230 includes a basis and two or more magnet poles of adverse polarity. In the embodiment shown in FIG. 2, two permanent magnets 235 and 236 of adverse polarity are shown. Some magnet assemblies as used in embodiments of the invention are described in more detail with respect to FIGS. 5a, 5b, 6a, and 6b.

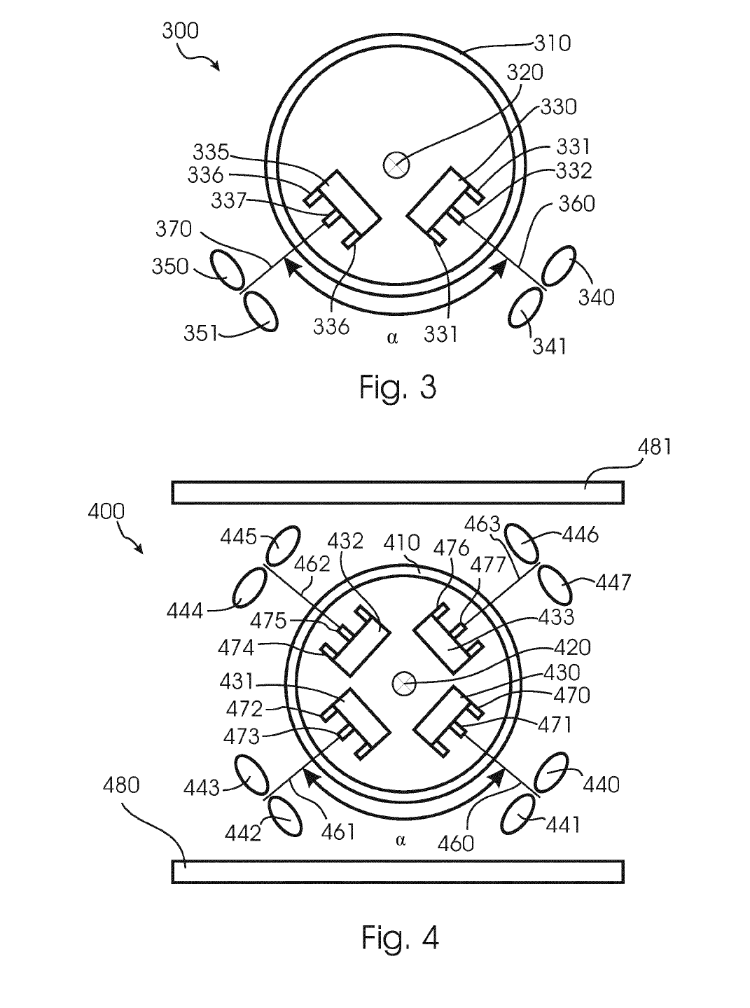

Typically, magnet poles as described with respect to FIGS. 2 to 4 are shown in a cross-sectional view. For instance, in the cross-sectional view of FIG. 2, the magnet element 235 may be provided by two outer magnet elements; however, the magnet elements may have a loop shape so that only one magnet element 235 may be present, being shown as two elements in the cross-sectional view of FIG. 2. The same applies for the magnet assemblies and the magnet elements of FIGS. 3 and 4.

According to some embodiments, the two magnet poles, such as magnets 235 and 236 generate two magnetic fields, which cause a plasma region to form near the magnetic fields during operation, when arranged in a deposition chamber. The plasma regions are denoted with reference signs 240 and 250 in FIG. 2.

In the following, magnetic assemblies may be described as providing plasma regions, which means that they are able to generate a magnetic field, which will cause a plasma region to form near the cathode assembly, when operated in a deposition chamber. For instance, the magnetic assemblies described herein will influence the generation and the location of a plasma region during a deposition process, which is described as providing a plasma region.

Typically, the plasma regions as described herein and shown in the figures are shown in a cross-sectional way. The cathode assemblies as described and shown in FIGS. 2 to 4 are shown in a cross-sectional view. Further, the plasma regions shown in the cross-sectional view may have a substantially circular or elliptical shape, but it is to be understood that this is only a schematic view of the plasma regions. The plasma regions may have a cross sectional shape, which deviates from the schematically shown shape and may have any shape, which may be caused by the magnetic fields of the magnetic assemblies as described herein. Typically, the two plasma regions shown in the figures, such as plasma regions 240 and 250 of FIG. 2, may have overlapping portions in a cross-sectional plane different from the plane shown in the FIGS. 2 to 4, or even may merge in another plane. For instance, in the case that the plasma region has a racetrack shape, the two plasma regions shown in the cross-sectional view may be one plasma region forming a closed loop shape. Nevertheless, the plasma regions described herein are referred to as being two plasma regions due to the fact that they are described in a cross-sectional view as shown in the figures.

The term “substantially” in this context means that there may be a certain deviation from the characteristic denoted with “substantially.” For instance, the term “substantially circular” refers to a shape which may have certain deviations from the exact circular shape, such as a deviation of about 1 to 10% of the general extension in one direction. According to a further example, the term “substantially symmetrical” may refer to the symmetry of the center points of the shapes of the elements denoted with “symmetrical.” Typically, the term “substantially symmetrical” may also mean that the elements are not exactly arranged symmetrically, but may deviate from the symmetrical arrangement to some extent, e.g. to some percent of the total extension of the element.

In the embodiment shown in FIG. 2, a first angular coordinate of the cathode assembly 200 for a magnet pole is denoted with reference sign 260 and a second angular coordinate of the cathode assembly 200 for a further magnet pole is denoted with reference sign 270. Typically, the first angular coordinate 260 and the second angular coordinate 270 extend from the rotary axis 220 of the cathode assembly 200 to the inner pole 236 of the magnet assembly 230 and one outer pole 235 of the magnet assembly 230, respectively. The angle α between the first angular coordinate 260 and the second angular coordinate 270 may be between about 20 degrees and about 160 degrees, as described above.

Typically, the magnet assembly is adapted for simultaneously generating two magnetic fields, which cause plasma regions to be formed near the cathode assembly. In that way, a first and the second plasma region are formed at the same time by the magnet poles of the magnet assembly, which allows for a large substrate area to be deposited at the same time with a high grade of uniformity.

FIG. 3 shows a cross-sectional view of a rotatable cathode assembly 300 according to embodiments described herein. The cathode assembly 300 has a rotary target assembly providing material 310 and a rotary axis 320 around which the target assembly may be rotated. Typically, the cathode assembly 300 provides a first magnet assembly 330 and a second magnet assembly 335. Each of the magnet assemblies 330 and 335 is typically arranged within the cathode assembly 300. Further, the magnet assembly 330 typically includes outer magnet poles 331 and an inner magnet pole 332, and magnet assembly 335 typically includes outer magnet poles 336 and an inner magnet pole 337. Examples for embodiments of magnet poles are described in detail with respect to FIGS. 5A, 5b, 6a, and 6b. The magnet poles of the magnet assemblies may be arranged so that the magnet assemblies generate one or more magnetic fields, which will cause one or more plasma regions to form near the cathode assembly, when the cathode assembly is operated in a deposition chamber. For instance, the plasma regions 340, 341 relate to the magnetic fields generated by magnet poles 331 and 332 of magnet assembly 330, and the plasma regions 350, 351 relate to the magnetic fields generated by magnet poles 336, 337 of magnet assembly 335. Typically, the inner magnet pole 332 of the magnet assembly 330 is oriented in a first angular coordinate 360 of the cathode assembly 300 and the inner magnet pole 337 of magnet assembly 335 is oriented in a second angular coordinate 370 of the cathode assembly 300. According to some embodiments, the first angular coordinate 360 and the second angular coordinate 370 extend from the rotary axis 320 of the cathode assembly 300 to the inner magnet poles of the two or more magnet assemblies of a cathode assembly, as described in detail above.

Typically, the magnet assemblies 330 and 335 are arranged in a fixed position with respect to the cathode assembly 300. In particular, the magnet assemblies 330 and 335 are held in a fixed position with respect to each other. According to some embodiments, the two magnet assemblies may be rigidly connected to each other so as to hold them in a fixed position with respect to each other. Generally, the side of the cathode at which the magnet assemblies 330 and 335 are arranged is referred to as the coating side.

Typically, an angle α is provided between the first angular coordinate for a magnet pole and the second angular coordinate for a further magnet pole. According to some embodiments, the angle α between the first angular coordinate and the second angular coordinate is typically between about 20 degrees and about 160 degrees, more typically between about 30 degrees and 120 degrees, and even more typically between about 50 and about 100 degrees. According to one embodiment, the angle between the first and the second angular coordinate is larger than about 30 degrees and smaller than about 80 degrees. In one example, the angle between the first and the second angular coordinate is about 60 degrees.

As shown in the embodiment of FIG. 3, each of the two or more magnet assemblies in a cathode assembly provides two plasma regions. However, FIG. 3 is a cross-sectional view of a cathode assembly so that also the plasma regions are shown in a cross-sectional view. As described above, the two plasma regions of one magnet assembly may overlap or merge in a plane different from the plane shown in FIG. 3.

According to some embodiments, a cathode assembly having more than one magnet assembly (such as the cathode assembly shown in FIG. 3) is used in a deposition chamber to coat one substrate. That means that more than one magnet assembly is used to coat the same substrate simultaneously. Typically, two magnet assemblies are both used in a fixed position to coat one substrate.

In FIG. 4, a cross-sectional view of a cathode assembly 400 according to embodiments described herein is shown. In the cathode assembly 400, a rotary target assembly provides target material 410. Exemplarily four magnet assemblies 430, 431, 432, and 433 are arranged within the cathode assembly 400. Typically, the target assembly is rotatable around rotary axis 420 and the magnet assemblies are fixed within the cathode assembly 400 with respect to the rotary axis 420. According to some embodiments, the magnet assemblies are in a fixed position relative to each other.

Typically, each of the magnet assemblies 430, 431, 432, and 433 includes inner magnet poles 471, 473, 475, and 477 as well as outer magnet poles 470, 472, 474, and 476. The magnet poles are typically adapted to provide one or more magnetic fields. The magnetic fields generated by the magnet poles 471, 472, 473, 474, 475, 476, and 477 of the magnet assemblies 430, 431, 432, and 433 may cause one or more plasma regions to form near the cathode assembly. For instance, magnet poles 471, 472, 473, 474, 475, 476, and 477 provide magnetic fields for forming plasma regions 440, 441, 442, 443, 444, 445, 446, and 447. Typically, the inner magnet poles 471 of magnet assembly 430 is arranged at a first angular coordinate 460 of the cathode assembly 400, the inner magnet pole 473 of magnet assembly 431 is arranged at a second angular coordinate 461 of the cathode assembly 400, the inner magnet pole 475 of magnet assembly 432 is arranged at a third angular coordinate 462 of the cathode assembly 400, and the inner magnet pole 477 of magnet assembly 433 is arranged at a fourth angular coordinate of the cathode assembly 400.

According to some embodiments, the magnet assemblies may be arranged symmetrically within the cathode assembly. As an example, the magnet assemblies 430, 431, 432, and 433 of the cathode assembly 400 are arranged substantially symmetrically within the cathode assembly 400. In one embodiment, the magnet assemblies may be arranged with the substantially same angular distance to each other. The angle α between the inner magnet poles of each of the magnet assemblies may then exemplarily be about 90 degrees.

According to further embodiments, the magnet assemblies may partly be arranged symmetrically. For instance, an arrangement having two magnet assemblies in one half of the cathode assembly may be mirrored in the other half of the cathode assembly. Such an example is shown in FIG. 4. Magnet assemblies 430 and 431 are symmetrical to assemblies 432 and 433. Typically, the cathode assembly shown in FIG. 4 may be described as having two coating sides; the magnet assemblies 430 and 431 are arranged at a first coating side and the magnet assemblies 432 and 433 are arranged at a second coating side. The two coating sides are also shown in FIG. 4 by substrates 480 and 481, each located at a respective one of the two coating sides.

According to some embodiments, each coating side of a cathode assembly may have one or more magnet assembly. Typically, each coating side of the cathode assembly may provide a first angular coordinate for a magnet pole and a second angular coordinate for a further magnet pole.

Typically, an arrangement of a first and a second magnet assembly may be placed twice in a cathode assembly, for instance, in a symmetrical way. According to some embodiments, the angle of about 60 degrees may be provided between a first angular coordinate of an inner magnet pole of the first magnet assembly and a second angular coordinate of an inner magnet pole of the second magnet assembly. With this arrangement, not only one substrate in front of the cathode assembly can be coated at a time, but another substrate being located behind the cathode assembly can also be coated symmetrically and simultaneously.

The embodiment shown in FIG. 4 shows exemplarily four magnet assemblies 430, 431, 432, and 433, each providing the magnetic field for two plasma regions. Typically, the angle α between the first angular coordinate 460 and the second angular coordinate 461 may be between about 20 degrees and about 160 degrees, more typically between about 30 degrees and 120 degrees, and even more typically between about 50 degrees and about 100 degrees. According to one embodiment, the angle between the first and the second angular coordinate is larger than about 30 degrees and smaller than about 80 degrees. In FIG. 4, only the angle between the first angular coordinate 460 and the second angular coordinate 461 is shown for the sake of clarity. However, the above described values for the angle α may also apply for the angles between the angular coordinates 461 and 462, 462 and 463, and 463 and 460.

FIG. 5a shows a cross sectional view of an example of a magnet assembly as may be used in the cathode assemblies according to embodiments described herein. Typically, the magnet assembly 500 includes a yoke 510. According to some embodiments, the magnet assembly 500 includes an inner magnet pole 520 and outer magnet poles 530 of adverse polarity. In the embodiment shown in FIGS. 5a and 5b, the magnet poles 520 and 530 are shown as magnet elements 520 and 530 arranged on the yoke 510. According to some embodiments, the magnet elements may be permanent magnets.

According to some embodiments, the magnet poles as described herein may be any element suitable for generating the magnetic field for forming a plasma region near the cathode assembly. In some embodiments, the magnet poles as described herein may be permanent magnets; according to further embodiments, one of the magnet poles may be provided by a magnetic material, such as a yoke made of an iron containing material.

Typically, as can be seen in FIG. 5a, the magnet elements 520 and 530 are arranged in a way that allows for two magnetic fields being generated. A part of the two magnetic fields is shown by magnetic field lines 560 and 540. In FIG. 5a, only magnetic field lines are shown extending from the permanent magnets in one direction, i.e. the direction pointing away from the yoke 510.

The magnetic fields shown in FIG. 5a may cause two plasma regions to be formed, when used in a cathode assembly as described above. The plasma regions formed by the magnet assembly 500 of FIG. 5a are denoted with reference signs 550 and 551 in FIG. 5a. Typically, FIG. 5a shows a cross-sectional view of a magnet assembly. Thus, also the two plasma regions 550, 551 are shown in a cross-sectional view. However, as also stated above, the plasma regions may have overlapping portions in a cross-sectional plane different from the plane shown, or even may merge in another plane. For instance, in the case that the plasma region has a racetrack shape, the two plasma regions shown in the cross-sectional view may be one plasma region forming a closed loop shape.

FIG. 5b shows a top view of the magnet assembly 500 of FIG. 5a. Typically, two magnet elements 520 and 530 can be seen on a yoke 510. The magnet elements may be arranged so that at least one of the magnet elements forms a closed loop. In FIG. 5b, it can be seen that the magnet element 520 forms a closed loop, in which the magnet element 530 is located.

According to some embodiments, a magnet element being arranged within a loop-formed magnet element may be denoted as an inner magnet, and the magnet element forming the loop may be denoted as an outer magnet. Typically, the inner magnet may form a structure within the outer magnet element.

Typically, the outer magnet pole as referred to herein may be shown as two outer poles in the cross sectional plane shown in the FIGS. 5a and 6a. However, as can be seen by the top view of the examples of FIGS. 5b and 6b, the outer magnet pole may be provided by one magnet element in a closed lop shape, which provides two outer poles in a cross-sectional view.

FIG. 6a shows a cross sectional view of an example of a magnet assembly as may be used in a cathode assembly as described above with respect to FIGS. 2 to 4. The magnet assembly 600 typically includes a yoke 610, on which magnet poles such as magnetic elements 620 and 630 may be arranged. According to some embodiments, the magnet elements 620 and 630 may be permanent magnets. In FIG. 6a, two plasma regions 650, 651 are shown, which may be provided by the magnet assembly 600, i.e. which may be caused to be formed and located during operation of the magnet assembly in a cathode assembly as described above.

Typically, the magnet assembly of FIG. 6a provides magnetic fields allowing the plasma regions to form. In FIG. 6a, magnetic field lines 640 and 660 are exemplarily shown, presenting a part of the generated magnetic field.

FIG. 6b provides a top view of the magnet assembly 600 of FIG. 6a. An outer magnet element 620 is provided, which surrounds an inner magnet element 630. In the embodiment shown in FIG. 6b, the inner magnet element as well as the outer magnet element is arranged in a loop-shape. Both magnet elements 620 and 630 are located on the yoke 610. Typically, in the case that the magnet assembly 600 is mounted in a cathode assembly, the inner magnet element 630 may be arranged at the first or second angular coordinate of a cathode assembly. According to some embodiments, where a loop-shaped inner magnet is used, the magnet assembly may be arranged so that an angular coordinate of the cathode assembly points to a centerline of the loop-shaped inner magnet element.

Typically, a first pole of a magnet assembly as described herein points into a direction outside the plane defined by the closed loop of at least one of the magnet elements. In other words, a pole of the magnet assembly points outside the plane defined by the yoke and points into the direction of the target material of a cathode assembly as exemplarily shown in FIGS. 2 to 4.

According to some embodiments, the cathode assembly and the magnet assemblies as described herein may be used as a rotatable cathode assembly during static deposition. That means that the substrate may be held in a fix position during the deposition process, whereas the cathode assembly may rotate around its rotary axis. Typically, the cathode assembly shown herein may be used for coating large area substrates.

According to some embodiments, large area substrates may have a size of at least 0.174 m². Typically the size can be about 1.4 m² to about 8 m², more typically about 2 m² to about 9 m² or even up to 12 m². Typically, the substrates, for which the structures, apparatuses, such as cathode assemblies, and methods according to embodiments described herein are provided, are large area substrates as described herein. For instance, a large area substrate can be GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

Typically, a substrate as described herein may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

According to some embodiments, the deposition material may be chosen according to the deposition process and the later application of the coated substrate. For instance, the deposition material of the target may be a material selected from the group consisting of: a metal, such as aluminum, molybdenum, titanium, copper, or the like, silicon, indium tin oxide, and other transparent oxides. Typically, the target material may be an oxide ceramic, more typically, the material may be a ceramic selected from the group consisting of an indium containing ceramic, a tin containing ceramic, a zinc containing ceramic and combinations thereof. For instance, the deposition material may be IGZO.

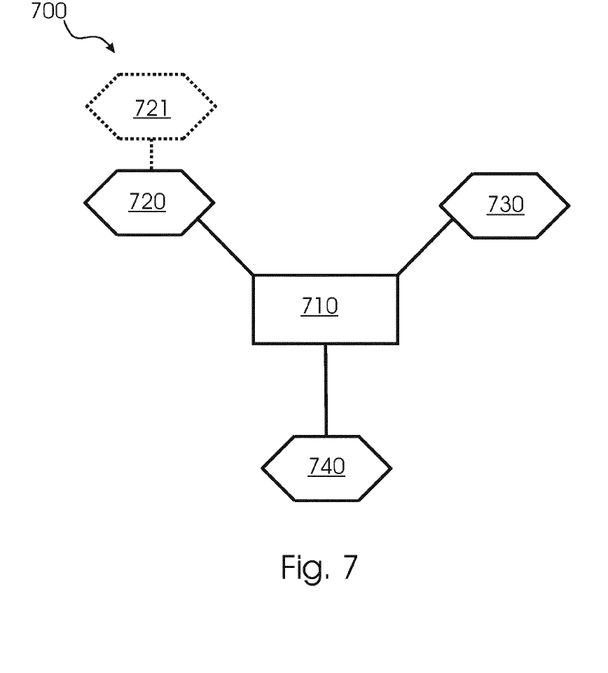

According to some embodiments, a method for depositing a film on a substrate is provided. An example of such a method can be seen in the schematic flow chart of FIG. 7. Typically, the method 700 includes generating at least two plasma regions, as indicated by block 710. Typically, the plasma regions are generated in a deposition chamber, such as a deposition chamber suitable for a PVD process. In the process chamber, a cathode assembly may be arranged having one or more magnet assemblies, as indicated by 720 as a first condition for the method 700. Typically, the cathode assembly may be a cathode assembly as described above with respect to FIGS. 2 to 4 and the one or more magnet assemblies in the cathode assemblies may be magnet assemblies as described above with respect to FIGS. 5a, 5b, 6a, and 6b. In FIG. 7, block 721 stands for the option that the cathode assembly is one of the cathode assemblies as shown in FIGS. 2 to 4 and is—as an option—shown in dashed lines.

According to some embodiments described herein, the cathode assembly used for generating a magnetic field causing the plasma region to be formed near the cathode assembly may be a rotatable cathode assembly, which is expressed by block 730. Typically, the cathode assembly is rotatable around a rotary axis and the magnet assembly/the magnet assemblies are arranged fixed with respect to the rotary axis.

Typically, the cathode assembly, which may be used to generate the plasma regions according to embodiments described herein, may provide a first angular coordinate for a magnet pole and a second angular coordinate for a further magnet pole. The magnet assembly/magnet assemblies used in the cathode assembly generally provide an inner magnet pole and at least one outer magnet pole. According to one embodiment, two plasma regions are generated by a cathode assembly having one magnet assembly. An inner magnet pole of the magnet assembly is arranged at the first angular coordinate of the cathode assembly and an outer magnet pole of the magnet assembly is arranged at the second angular coordinate of the cathode assembly. According to a further embodiment, an inner magnet pole of a first magnet assembly is arranged at the first angular coordinate of the cathode assembly and an inner magnet pole of a second (or further) magnet assembly is arranged at the second angular coordinate of the cathode assembly. For instance, the cathode assembly used for the method for depositing a film in a substrate may be a cathode assembly as described with respect to FIG. 2 or FIG. 3. Typically, the magnet assembly/magnet assemblies are arranged at a coating side of the cathode assembly for coating a substrate.

According to some embodiments, block 740 refers to the arrangement of the first and second angular coordinate, and in particular to the angle between the first and second angular coordinate. Typically, the angle is between about 20 degrees and about 160 degrees, more typically between about 30 degrees and 120 degrees, and even more typically between about 50 and about 100 degrees. According to one embodiment, the angle between the first and the second angular coordinate is larger than about 30 degrees and smaller than about 80 degrees. In one example, the angle between the first and the second angular coordinate is about 60 degrees.

A cathode assembly for a sputter deposition apparatus having a coating side for coating on a substrate is provided. The cathode assembly includes a rotary target assembly adapted for rotating a target material around a rotary axis and at least a first magnet assembly. The at least one magnet assembly has typically an inner magnet pole and at least one outer magnet pole and being adapted for generating one or more plasma regions. Further, the cathode assembly has a first angular coordinate for a magnet pole and a second angular coordinate for a further magnet pole. Typically, the magnet poles being provided for the coating side. The first angular coordinate and the second angular coordinate define an angle α larger than about 20 degrees and smaller than about 160 degrees. According to some embodiments, the inner magnet pole of the first magnet assembly is provided at the first angular coordinate and the outer magnet pole of the first magnet assembly is provided at the second angular coordinate. Typically, the cathode assembly may include a second magnet assembly having an inner magnet pole and at least one outer magnet pole. The second magnet assembly may be adapted for generating one or more plasma regions. In the case that a second magnet assembly is provided, the inner magnet pole of the first magnet assembly is provided at the first angular coordinate and the inner magnet pole of the second magnet assembly is provided at the second angular coordinate. According to some embodiments, the first and/or second magnet assembly are held in a fixed position with respect to the rotary axis of the cathode assembly. Typically, the first and/or the second magnet assembly may each provide two plasma regions. In one embodiment, which can be combined with other embodiments described herein, the first angular coordinate and the second angular coordinate may form an angle α larger than about 30 degrees and smaller than about 80 degrees. Typically, the magnet assembly may be located within the target assembly. In one typical embodiment, the magnet assembly may be adapted for generating two or more plasma regions simultaneously. Further, a cathode assembly may be provided, which typically includes more than one magnet assembly, which are arranged in the cathode assembly in a substantially symmetrical way.

According to some embodiments described herein, a magnet pole of the first and/or second magnet assembly may include magnet elements arranged to form a closed loop. In particular, a magnet pole of the first and/or second magnet assembly typically may include magnet elements arranged to form a structure within the closed loop. In some embodiments, a magnet pole of the first and/or second magnet assembly may point into a direction outside of the plane defined by the closed loop. Typically, at least two magnet assemblies may be rigidly connected with each other. According to some embodiments, the at least two magnet assemblies may be adapted to coat the same substrate simultaneously.

In a further aspect, a method for depositing a film on a substrate in a sputter deposition apparatus is provided. The sputter deposition apparatus may include a rotary target assembly and a coating side for coating on a substrate. Typically, the target assembly is adapted for rotating a target material around a rotary axis. Further, the cathode assembly may include at least one magnet assembly held in a fixed position with respect to the rotary axis. The magnet assembly includes an inner magnet pole and at least one outer magnet pole and is adapted for generating one or more plasma regions. Typically, the cathode assembly further has a first angular coordinate for a magnet pole, the magnet pole being provided for the coating side, and a second angular coordinate for a further magnet pole, the magnet pole being provided for the coating side. The method for depositing a film on a substrate includes generating at least one first plasma region with a magnetic field generated by a magnet pole being arranged in the first angular coordinate and at least one second plasma region with a magnetic field generated by a magnet pole being arranged in the second angular coordinate for coating the substrate at the coating side. Typically, the first angular coordinate and the second angular coordinate define an angle α larger than about 20 degrees and smaller than about 160 degrees. According to some embodiments described herein, the first angular coordinate and the second angular coordinate may form an angle α larger than about 30 degrees and smaller than about 80 degrees.

Typically, the above described cathode assemblies can be described as multidirectional racetrack cathodes due to the angle between the magnet poles of the magnet assemblies, which are oriented in different directions. By arranging one or more magnet assemblies into one cathode as described above, comparable film properties can be achieved as with a cathode assembly providing split sputter mode or continuous wobbling. However, with the cathode assembly according to embodiments described herein, there is no need for turning parts within the cathode. Further, due to the fact that the magnet assemblies in one cathode assembly according to embodiments of the present invention are operated simultaneously, the film properties can be achieved in shorter time, compared to a cathode assembly with split sputter mode or continuous wobbling. Also, the above described racetrack arrangement can be symmetrically mirrored to the backside of the cathode assembly to achieve simultaneous coating on substrates located on both sides of the cathode assembly.

While the foregoing is directed to embodiments of the invention, other and further embodiments of the invention may be devised without departing from the basic scope thereof, and the scope thereof is determined by the claims that follow.

1. Cathode assembly for a sputter deposition apparatus having a coating side for coating on a substrate, the cathode assembly comprising:
a rotary target assembly adapted for rotating a target material around a rotary axis;
at least a first magnet assembly held in a fixed position with respect to the rotary axis and having an inner magnet pole and at least one outer magnet pole and being adapted for generating one or more plasma regions;
the cathode assembly has a first angular coordinate for a magnet pole, the magnet pole being provided for the coating side, and a second angular coordinate for a further magnet pole, the magnet pole being provided for the coating side; and
wherein the first angular coordinate and the second angular coordinate define an angle α larger than about 20 degrees and smaller than about 160 degrees.

2. The cathode assembly according to claim 1, wherein the inner magnet pole of the first magnet assembly is provided at the first angular coordinate and the at least one outer magnet pole of the first magnet assembly is provided at the second angular coordinate.

3. The cathode assembly according to claim 1, further comprising a second magnet assembly having an inner magnet pole and at least one outer magnet pole and being adapted for generating one or more plasma regions, wherein the inner magnet pole of the first magnet assembly is provided at the first angular coordinate and the inner magnet pole of the second magnet assembly is provided at the second angular coordinate.

4. The cathode assembly according to claim 1, wherein the first magnet assembly provides two plasma regions.

5. The cathode assembly according to claim 1, wherein the first angular coordinate and the second angular coordinate form an angle α larger than about 30 degrees and smaller than about 80 degrees.

6. The cathode assembly according to claim 1, wherein the magnet assembly is located within the target assembly.

7. The cathode assembly according to claim 1, wherein the magnet assembly is adapted for generating two or more plasma regions simultaneously.

8. The cathode assembly according to claim 1, wherein the cathode assembly comprises more than one magnet assembly and the arrangement of the magnet assemblies in the cathode assembly is substantially symmetrical.

9. The cathode assembly according to claim 1, wherein a magnet pole of the first magnet assembly comprises magnet elements arranged to form a closed loop.

10. The cathode assembly according to claim 3, wherein a magnet pole of the first and second magnet assembly comprises magnet elements arranged to form a structure within a closed loop.

11. The cathode assembly according to claim 10, wherein a magnet pole of the magnet elements is pointing into a direction outside of the plane defined by the closed loop.

12. The cathode assembly according to claim 11, wherein the at least two magnet assemblies are rigidly connected with each other.

13. The cathode assembly according to claim 12, wherein the at least two magnet assemblies are adapted to coat the same substrate simultaneously.

14. Method for depositing a film on a substrate in a sputter deposition apparatus having a rotary target assembly and having a coating side for coating on a substrate, the target assembly being adapted for rotating a target material around a rotary axis; wherein the cathode assembly comprises at least one magnet assembly held in a fixed position with respect to the rotary axis and having an inner magnet pole and at least one outer magnet pole and being adapted for generating one or more plasma regions; the cathode assembly further comprises a first angular coordinate for a magnet pole, the magnet pole being provided for the coating side, and a second angular coordinate for a further magnet pole, the magnet pole being provided for the coating side; the method comprising:
generating at least one first plasma region with a magnetic field generated by a magnet pole being arranged in the first angular coordinate and at least one second plasma region with a magnetic field generated by a magnet pole being arranged in the second angular coordinate for coating the substrate at the coating side;
wherein the first angular coordinate and the second angular coordinate define an angle a larger than about 20 degrees and smaller than about 160 degrees.

15. The method according to claim 14, wherein the first angular coordinate and the second angular coordinate form an angle a larger than about 30 degrees and smaller than about 80 degrees.

16. The cathode assembly according to claim 2, wherein the second magnet assembly provides two plasma regions.

17. The cathode assembly according to claim 3, wherein the first and the second magnet assembly each provide two plasma regions.

18. The cathode assembly according to claim 1, wherein the first angular coordinate and the second angular coordinate form an angle α between about 50 and about 100 degrees.

19. The cathode assembly according to claim 3, wherein a magnet pole of at least one of the first magnet assembly and the second assembly comprises magnet elements arranged to form a closed loop.

20. The cathode assembly according to claim 3, wherein the first magnet assembly and the second magnet assembly are both provided in a fixed position with respect to each other to coat the same substrate.
